(19) United States
(12) Patent Application Publication
(10) Pub. No.: US 2017/0040441 A1
(43) Pub. Date: Feb. 9, 2017

(54) VERTICAL SEMICONDUCTOR DEVICE

(71) Applicants: KABUSHIKI KAISHA TOYOTA CHUO KENKYUSHO, Nagakute-shi (JP); TOYOTA JIDOSHA KABUSHIKI KAISHA, Toyota-shi (JP); DENSO CORPORATION, Kariya-shi (JP)

(72) Inventors: Sachiko AOI, Nagakute-shi (JP); Yukihiko WATANABE, Nagakute-shi (JP); Katsumi SUZUKI, Nagakute-shi (JP); Naohiro SUZUKI, Anjo-shi (JP)

(73) Assignees: KABUSHIKI KAISHA TOYOTA CHUO KENKYUSHO, Nagakute-shi (JP); TOYOTA JIDOSHA KABUSHIKI KAISHA, Toyota-shi (JP); DENSO CORPORATION, Kariya-shi (JP)

(21) Appl. No.: 15/101,165

(22) PCT Filed: Dec. 22, 2014
(86) PCT No.: PCT/JP2014/006389

§ 371 Date: Jun. 2, 2016

(30) Foreign Application Priority Data
Dec. 27, 2013 (JP) 2013-271579

(51) Int. Cl. H01L 29/739; H01L 29/06; H01L 29/10; H01L 29/16

(52) U.S. Cl. CPC H01L 29/7397; H01L 29/1608; H01L 29/0623; H01L 29/1095

(57) ABSTRACT

A resurf layer and a guard ring are formed in a peripheral region in a position at the surface of the semiconductor substrate. The guard ring is formed more deeply than the resurf layer. When the guard ring is shallow and the impurity concentration of the resurf layer is low, the potential distribution at the deep portion of the resurf layer becomes unstable, and the resurf layer does not sufficiently exhibit the effect of improving the withstand voltage. When the guard ring is deep, the impurity concentration of the guard ring is high, the potential distribution at the deep portion of the resurf layer is regulated by the guard ring and the resurf layer sufficiently exhibits the effect of improving the withstand voltage.

### TECHNICAL FIELD

A vertical semiconductor device that comprises a front surface electrode formed on the front surface of a semiconductor substrate and a rear surface electrode formed on the rear surface of the semiconductor substrate, and is capable of varying the resistance between the front surface electrode and the rear surface electrode is disclosed in this specification. In particular, a vertical semiconductor device that comprises an element region in which a semiconductor structure for varying the resistance is formed and a peripheral region circulating around the element region is disclosed.

### BACKGROUND ART

Vertical semiconductor devices in which a voltage applied to a gate electrode changes the resistance between a front surface electrode and a rear surface electrode are known. A MOS comprises a body region separating a source region and a drift region, and a gate electrode facing the body region through a gate insulation film. Or an IGBT comprises a body region separating an emitter region and a drift region, and a gate electrode facing the body region through a gate insulation film. In either case, they comprise a second conductivity type region (body region) separating a front surface side first conductivity type region (a source region or an emitter region) and a rear surface side first conductivity type region (drift region), and the gate electrode facing the second conductivity type region through the gate insulation film. When ON-voltage is applied to the gate electrode, a range facing the gate electrode through the gate insulation film in the second conductivity type region (body region) is inverted to the first conductivity, and the resistance between the front surface electrode and the rear surface electrode decreases.

When the voltage applied between the front surface electrode and the rear surface electrode is increased, even if the ON-voltage is not applied to the gate electrode, a phenomenon occurs in which current flows between the front surface electrode and the rear surface electrode. In this specification this phenomenon is referred to as a burst of withstand voltage. In order to increase the withstand voltage, various improvements are made in a semiconductor structure formed in an element region.

When the voltage applied between the front surface electrode and the rear surface electrode is increased, even if the semiconductor structure formed in the element region is improved, current flows between the front surface electrode and the rear surface electrode through a peripheral region of the semiconductor substrate. The semiconductor structure in the peripheral region also requires improvement in order to improve the withstand voltage.

A technology to form a second conductivity type impurity region in a range facing the front surface of a semiconductor substrate, circulating around the element region is disclosed In Patent Literatures 1 and 2. Since it circulates around the element region, it is in a ring shape. According to the technology in Patent Literatures 1 and 2, a plurality of ring-like regions are multiply arranged around the element region. In this specification this technology is referred to as a guard ring structure. A guard ring structure arranged in the peripheral region improves the withstand voltage in the peripheral region.

In FIG. 9 of Patent Literature 1, a technology to form a second conductivity type region (in Patent Literature 1 this is referred to as a P+potential fixed layer) at an intermediate depth of the rear surface side first conductivity type region (drift region) is disclosed in order to further improve the withstand voltage in the peripheral region in addition to the guard ring structure. According to the technology of Patent Literature 1, a plurality of second conductivity type regions are arranged at intervals (i.e., at positions separate from each other).

In Patent Literature 2, a technology to form a second conductivity type impurity layer (in Patent Literature 2 this is referred to as a resurf layer) in a range facing the front surface of a semiconductor substrate is disclosed in order to improve the withstand voltage in the peripheral region in addition to the guard ring structure. Both the resurf layer and the guard ring are a second conductivity type, however, since the former's impurity concentration ratio is thinner than the latter's impurity concentration ratio, the resurf layer can be distinguished from the guard ring. In Patent Literature 2, the guard ring structure is formed in a range enclosed by the resurf layer.

### CITATION LIST

### Patent Literature

[Patent Literature 1] Japanese Patent Application Publication No. 2007-311822
[Patent Literature 2] Japanese Patent Application Publication No. 2003-101039

### SUMMARY OF INVENTION

### Solution to Problem

In order to protect a semiconductor device from bursting, it is necessary to improve the withstand voltage in a peripheral region.

According to the structure of “arranging a guard ring structure and a plurality of second conductivity type regions at an intermediate depth of a rear surface side first conductivity type region at intervals” described in Patent Literature 1, a depletion layer does not fully develop from an interface between the second conductivity type region at intervals and the rear surface side first conductivity type region. Hence it cannot fully improve the withstand voltage in the peripheral region.

The structure of “arranging a guard ring structure inside a resurf layer” described in Patent Literature 2 cannot fully improve the withstand voltage in the peripheral region, either. It presents a problem in that particularly when a semiconductor substrate is formed of SiC, since the resistance of the resurf layer is high, the depletion layer does not expand in the resurf layer.
This specification proposes a semiconductor structure to fully improve the withstand voltage in the peripheral region.

### Means for Solving the Problem

The semiconductor device disclosed in this specification comprises an element region and a peripheral region circulating the element region when the semiconductor substrate is in a planar view.

The element region comprises; a front surface electrode formed on the front surface of a semiconductor substrate, a rear surface electrode formed on the rear surface of the semiconductor substrate, a front surface side first conductivity type region conductive to the front surface electrode (in a MOS it is a source region, and in an IGBT it is an emitter region), a rear surface side first conductivity type region conductive to the rear surface electrode (drift region), a second conductivity type region (body region) separating the front surface side first conductivity type region and the rear surface side first conductivity type region, and a gate electrode facing the second conductivity type region through a gate insulation film at a position separating the front surface side first conductivity type region and the rear surface side first conductivity type region. With the above semiconductor structure, the voltage of the gate electrode changes the resistance between the front surface electrode and the rear surface electrode.

The peripheral region of the semiconductor device disclosed in this specification comprises a multiple structure of a second conductivity type low impurity concentration layer formed in a range facing the front surface of the semiconductor substrate and a second conductivity type high impurity concentration ring-like region circulating the element region in a range facing the front surface of the semiconductor substrate. The second conductivity type layer and the second conductivity type ring-like region formed in the peripheral region both include second conductivity type impurities, however, the former's impurity concentration ratio is thinner than the latter's impurity concentration ratio. In this specification, the former is referred to as a second conductivity type low impurity concentration layer, while the latter is referred to as a second conductivity type high impurity concentration ring-like region.

The technology to form the second conductivity type low impurity concentration layer and the second conductivity type high impurity concentration ring-like region in the range facing the front surface of the semiconductor substrate in the peripheral region of the semiconductor device is described in Patent Literature 2. However, this technology only is not enough to improve the withstand voltage in the peripheral region. After the research the cause thereof was identified.

The second conductivity type low impurity concentration layer has a low impurity concentration ratio and high resistance. The second conductivity type high impurity concentration ring-like region is formed in the second conductivity type low impurity concentration layer and the resistance of the ring-like region of high concentration ratio is low. The range to form the second conductivity type high impurity concentration ring-like region is more shallow than the range to form the second conductivity type low impurity concentration layer. An electrical potential at a deep portion of the second conductivity type low impurity concentration layer becomes very different from the electrical potential of the second conductivity type high impurity concentration ring-like region. Once the electrical potential of the deep portion of the second conductivity type low impurity concentration layer is not regulated by the electrical potential of the second conductivity type high impurity concentration ring-like region, it is difficult to obtain a sufficient effect in improving the withstand voltage by using the second conductivity type low impurity concentration layer together with the second conductivity type high impurity concentration ring-like region. According to the conventional technology, the second conductivity type low impurity concentration layer was used together with the second conductivity type high impurity concentration ring-like region, however, the latter was more shallow than the former, hence it was found out that the intended effect was not obtained.

The technology disclosed in this specification was created based on the above findings. According to the semiconductor device disclosed in this specification, the second conductivity type high impurity concentration ring-like region extends more deeply to the rear surface side than the second conductivity type low impurity concentration layer.

According to the above semiconductor device, a combination of “the second conductivity type low impurity concentration layer and the second conductivity type high impurity concentration ring-like region” is formed in the peripheral region of the semiconductor substrate, in which the second conductivity type high impurity concentration ring-like region with low resistance extends more deeply than the second conductivity type low impurity concentration layer with high resistance.

According to the above structure, the second conductivity type high impurity concentration ring-like region with low resistance reaches the deep portion of the second conductivity type low impurity concentration layer with high resistance, in which the electrical potential of the deep portion of the second conductivity type low impurity concentration layer is regulated by the electrical potential of the second conductivity type high impurity concentration ring-like region. Then the technology using the second conductivity type low impurity concentration layer together with the second conductivity type high impurity concentration ring-like region works as intended, in which the depletion layer expands in a wide range of the second conductivity type low impurity concentration layer. Hence the withstand voltage in the peripheral region is fully improved.

It is desirable that the second conductivity type low impurity concentration layer be conductive to the front surface electrode. In order to do so, the second conductivity type high impurity concentration region is formed on a partial front surface of the second conductivity type low impurity concentration layer such that it forms an ohmic contact with the front surface electrode. In this case, it is desirable that the depth of the second conductivity type high impurity concentration region is less than the depth of the second conductivity type low impurity concentration layer, which is less than the depth of the second conductivity type high impurity concentration ring-like region.

Furthermore, it is desirable that the impurity concentration ratio of the second conductivity type high impurity concentration region is larger than the impurity concentration ratio of the second conductivity type high impurity concentration ring-like region, which is larger than the impurity concentration ratio of the second conductivity type low impurity concentration layer.

### BRIEF DESCRIPTION OF DRAWINGS

FIG. 1 A cross sectional view of a range extending from the element region to the peripheral region of the semiconductor device of Embodiment 1.

FIG. 2 A cross sectional view of a range extending from the element region to the peripheral region of the semiconductor device of Embodiment 2.

FIG. 3 A cross sectional view of a range extending from the element region to the peripheral region of the semiconductor device of Embodiment 3.

FIG. 4 A graph illustrating a relationship among the withstand voltage of the peripheral region, the depth of the resurf layer, and the depth of the guard ring.

FIG. 5 A graph illustrating a relationship among the withstand voltage of the peripheral region, the impurity concentration ratio of the contact region, the impurity concentration ratio of the resurf layer, and the impurity concentration ratio of the guard ring.

### DESCRIPTION OF THE EMBODIMENTS

The technical features disclosed in this specification are arranged below. The matters described below independently have a technical usefulness individually.

(First feature) The semiconductor substrate is SiC and the semiconductor device is a MOS. In this specification, the first conductivity type is an n-type while the second conductivity type is a p-type. In the element region, a laminated structure is formed from the front surface to the rear surface of the semiconductor substrate, in which a front surface side first conductivity type region (n-type source region), a second conductivity type region (p-type body region), a rear surface side first conductivity type region (n-type drift region), and a first conductivity type region (n-type drain region) are laminated in this order. A trench which passes through the n-type source region and the p-type body region reaching the n-type drift region is formed from the front surface of the semiconductor substrate. The walls of the trench are covered with a gate insulation film and a trench gate electrode is filled therein.

(Second feature) The second conductivity type (p-type) impurity low concentration layer formed in the peripheral region continues to the p-type body region, which is referred to as a resurf layer. The second conductivity type high impurity concentration ring-like region multiply surrounds the element region, which is referred to as a guard ring.

(Third feature) The semiconductor substrate is formed of SiC, and a second conductivity type high impurity concentration region which forms an ohmic contact with the front surface electrode is formed on a partial surface of the second conductivity type low impurity concentration layer. The impurity concentration ratio of the second conductivity type high impurity concentration region is larger than the impurity concentration ratio of the second conductivity type high impurity concentration ring-like region, which is larger than the impurity concentration ratio of the second conductivity type low impurity concentration layer.

### EMBODIMENTS

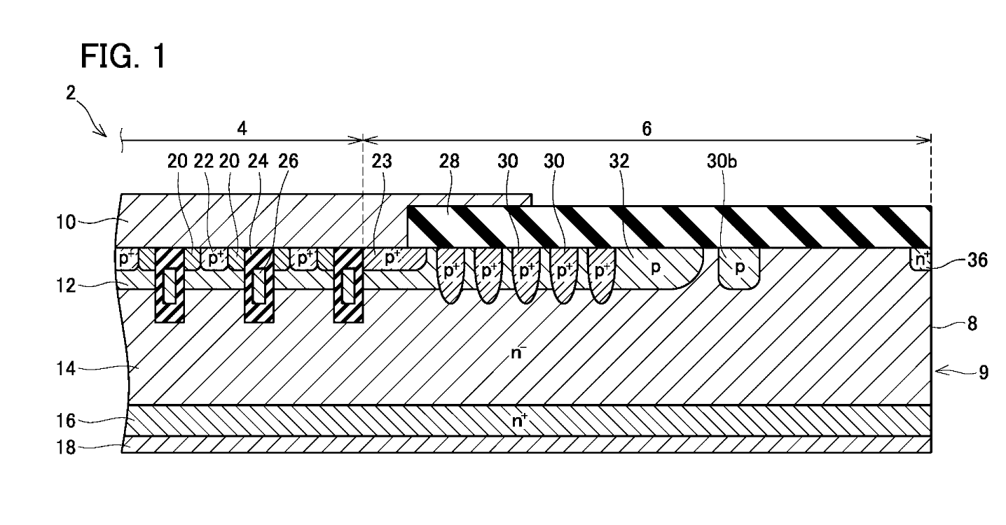

FIG. 1 illustrates a cross sectional view of a region extending from the element region 4 of the vertical semiconductor device 2 of Embodiment 1 operating as a MOS to the peripheral region 6. The reference numeral 8 indicates the outer circumference of the semiconductor substrate 9. The element region 4 continuously extends to the left in FIG. 1. The semiconductor substrate 9 is formed of SiC.

The reference numeral 10 is a front surface electrode formed on the front surface of the semiconductor substrate 9, which becomes a source electrode of the MOS. The reference numeral 18 is a rear surface electrode formed on the rear surface of the semiconductor substrate 9, which becomes a drain electrode of the MOS.

A trench extends from the front surface of the semiconductor substrate 9 to the rear surface. The walls of the trench are covered with a gate insulation film 24 and a trench gate electrode 26 is filled therein.

A lamination structure laminated with a source region 20, a body region 12, and a drift region 14 in this order from the front surface side of the semiconductor substrate is formed in facing positions on the sides of the trench gate electrode 26 through the gate insulation film 24. In this embodiment, the first conductivity type is an n-type and the second conductivity type is a p-type. The source region 20 is an n-type and an embodiment of the front surface side first conductivity type region. The body region 12 is a p-type and an embodiment of the second conductivity type region. The drift region 14 is an n-type and an embodiment of the rear surface side first conductivity type region. A drain region 16 is formed between the drift region 14 and the rear surface electrode (drain electrode) 18. The drain region 16 is an n-type and an embodiment of the first conductivity type region. A body region 12 faces the sides of the trench gate electrode 26 separating the source region 20 and the drift region 14 through the gate insulation film 24. The reference numeral 22 is a body contact layer forming an ohmic contact with the front surface electrode (source electrode) 10, maintaining the potential of the body region 12 to the source potential.

The impurity concentration of the source region 20 is high enough to form an ohmic contact with the front surface electrode (source electrode) 10. The impurity concentration of the body region 12 is such low that the facing ranges in the sides of the trench gate electrode 26 through the gate insulation film 24 is inverted to the n-type when a positive voltage is applied to the trench gate electrode 26. When the voltage is not applied to the trench gate electrode 26, the impurity concentration of the drift region 14 is such low that the depletion layer extends from the interface of the body region 12 and the drift region 14 to a large range of the drift region 14. The impurity concentration of the drain region 16 is concentrated enough to form an ohmic contact with the rear surface electrode (drain electrode) 18.

With the above semiconductor structure, when a positive voltage is applied to the trench gate electrode 26, the portion of the body region 12 which is a range opposing on the sides of the trench gate electrode 26 through the gate insulation film 24 is inverted to an n-type, decreasing the resistance between the front surface electrode (source electrode) 10 and rear surface electrode (drain electrode) 18. When the positive voltage is not applied to the trench gate electrode 26, the depletion layer expands from the interface of the body region 12 and the drift region 14 to a wide range of the body region 12 and the drift region 14, in which it is possible to obtain high withstand voltage.

A peripheral withstand voltage structure is formed in the outer peripheral side of the semiconductor substrate 9 rather than the outermost trench. In this specification, the range inside the outermost trench is referred to as an element region 4 and the range outside it is referred to as a peripheral region 6.

In the peripheral region 6, a resurf layer 32 and a group of guard rings 30 are formed. For convenience of the illustration, the reference numeral 30 is given only to a part of the guard rings. The resurf layer 32 is a p-type and the impurity concentration ratio thereof is lower than that of the guard ring group 30. The resurf layer 32 is an embodiment of the second conductivity type low impurity concentration layer. The impurity concentration ratio of the resurf layer 32 may be uniform, however, it may become gradually thinner as it approaches the outer circumference 8 of the semiconductor substrate 9. Each guard ring 30 is also a p-type and an embodiment of the second conductivity type high impurity concentration ring-like region. A plurality of guard rings 30 are formed. A plurality of guard rings 30 multiply surround the element region 4. The outermost guard ring 30b is formed outside of the resurf layer 32. The guard ring formed outside of the resurf layer 32 may not exist, or one or more guard rings may be formed. The surface of the semiconductor substrate 9 is covered with the insulation film 28 in the peripheral region 6. An n-type high impurity concentration region 36 is formed on the front surface side at a position in contact with the outer circumference 8 of the semiconductor substrate. A contact region 23 is formed in a range adjacent to the outside of the outermost trench. A partial surface of the contact region 23 is not covered with the insulation film 28 and forms an ohmic contact with the front surface electrode 10.

Each guard ring 30 extends more deeply to the rear surface side than the resurf layer 32. That is to say, the guard rings 30 are formed more deeply than the resurf layer 32. The resurf layer 32 is high resistance and the potential does not become uniform. A potential distribution occurs in the resurf layer 32. In contrast, the guard ring 30 is low resistance and the potential becomes uniform. However, the potentials of adjacent guard rings are different. As illustrated in FIG. 1, when the guard rings with low resistance 30 reache deeply into the resurf layer with high resistance 32, the potential at the deep portion of the resurf layer 32 is regulated by the potential of the guard rings 30. Then the depletion layer expands in a wide range of the resurf layer 32. A phenomenon in which the resurf layer 32 improves the withstand voltage in the peripheral region 6 occurs as intended, and the withstand voltage improves in the peripheral region 6.

The contact region 23 and the resurf layer 32 are manufactured by injecting phosphorus since the diffusion length thereof can be short. The guard rings 30 can be manufactured by injecting phosphorus, however, it is more advantageous to manufacture them by injecting boron because of the deep diffusion.

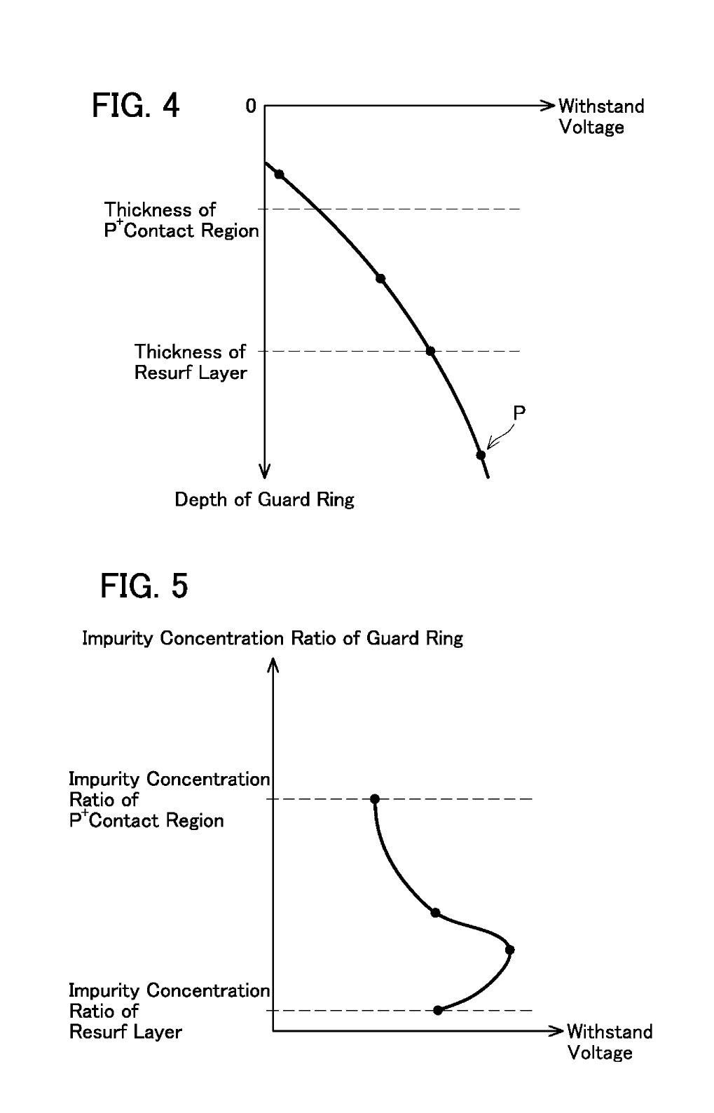

The vertical axis in FIG. 4 illustrates the depth of the guard rings 30 formed, indicating it becomes thicker as it reaches downward. The horizontal axis indicates the withstand voltage of the peripheral region 6. As illustrated in FIG. 4, it is verified that the more deeply the guard ring 30 is formed, the more the withstand voltage increases. It is understood that if it is formed more deeply than the thickness of the resurf layer 32, i.e., the guard ring 30 extends longer to the rear surface side than the resurf layer 32, the withstand voltage improves more effectively.

It is verified that according to the conventional structure, the guard ring 30 is thinner than the resurf layer 32 and the resurf layer 32 is not effective in improving the withstand voltage.

FIG. 5 illustrates the withstand voltage at the point P of FIG. 4 when the impurity concentration ratio of the guard ring 30 is changed. The impurity concentration ratio of the guard ring 30 clearly affects the withstand voltage. It is verified that when it is higher than the impurity concentration ratio of the resurf layer 32 and lower than the impurity concentration ratio of the contact region 23, the resurf layer 32 is sufficiently effective in improving the withstand voltage.

### Embodiment 2

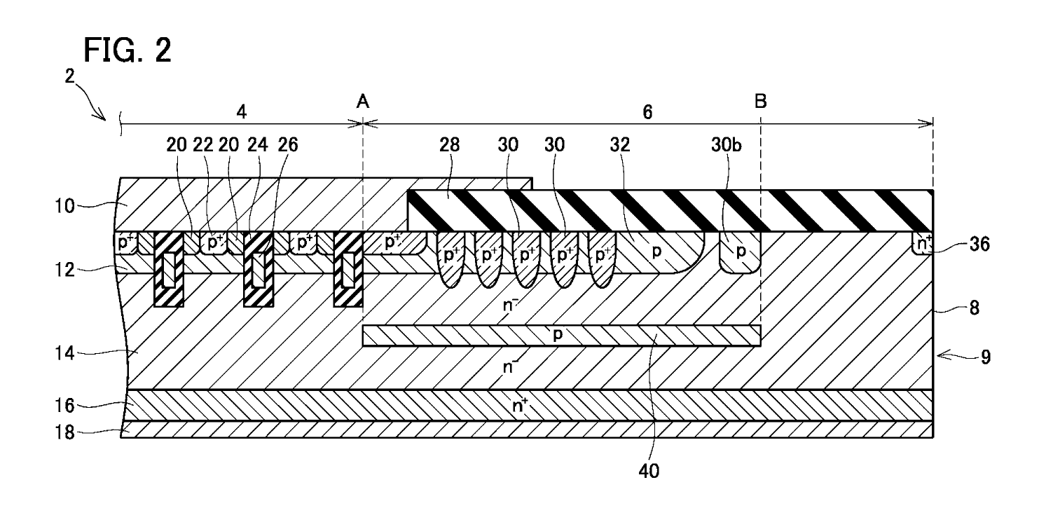

As illustrated in FIG. 2, in the peripheral region 6 of the semiconductor device of Embodiment 2, a p-type layer 40 is formed at an intermediate depth of the drift region 14. The p-type layer 40 is floating surrounded by an n-type drift region 14. The p-type layer 40 is an embodiment of the second conductivity type floating layer. The p-type layer 40 is continuously formed from the bordering position A of the element region 4 and the peripheral region 6 to the existing position B of the outermost guard ring 30b. The same parts as Embodiment 1 are given the same reference numerals so as to omit repeated descriptions.

It is desirable that the second conductivity type floating layer (p-type layer) 40 continuously extend without a break from an inner position of the innermost guard ring to an outer peripheral position of the resurf layer. It is desirable that when the outermost guard ring is on the inner peripheral side of the resurf layer than a position on the outer peripheral side, it continuously extend without a break to the position on the outermost guard ring.

Using the guard ring group 30 deeper than the resurf layer 32 together with the p-type floating layer 40 further improves the withstand voltage of the peripheral region.

### Embodiment 3

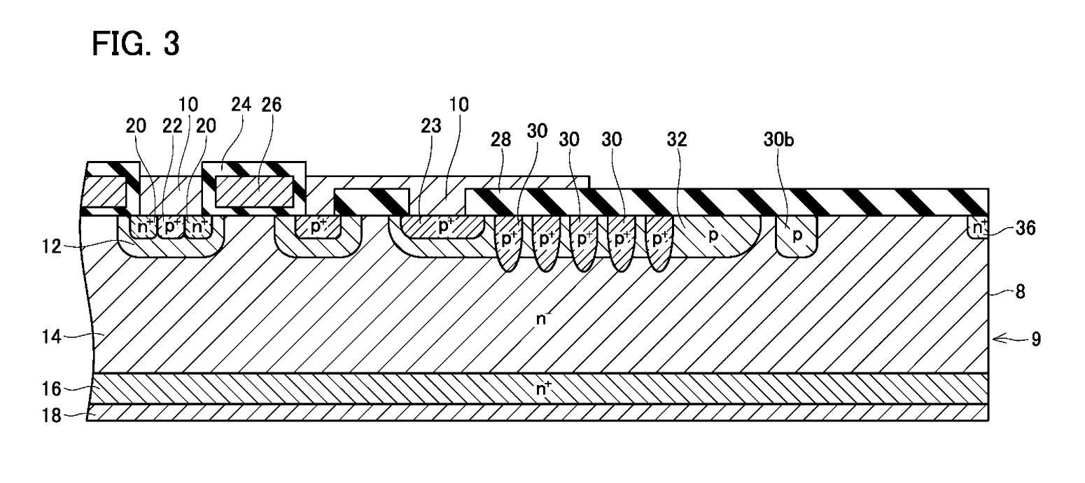

As illustrated in FIG. 3, a planer gate electrode 26 may be used as a gate electrode. The same parts as Embodiment 1 are given the same reference numerals so as to omit repeated descriptions. In this embodiment, also, when a positive voltage is applied to the planer gate electrode 26, an inversion layer is formed in the body region 12 positioned separating the source region 20 and the drain region 14, decreasing the resistance between the front surface electrode 10 and rear surface electrode 18. In the case of a vertical semiconductor device using the planer gate electrode 26, when the resurf layer 32 is provided in the peripheral region so as to form a deeper guard ring group 30 than the resurf layer 32, the withstand voltage of the semiconductor device is improved.

Specific examples of this invention have been detailed above, however, these are merely illustrations and they do not limit the scope of the claims. The technologies described in the scope of the claims include various modifications and changes of the specific examples illustrated above.

For example, the first conductivity type may be a p-type, while the second conductivity type may be an n-type. Also it may be applied to an IGBT instead of a MOS.

The technological elements described in this specification or drawings exhibit technological usefulness by themselves or combining them, and they are not limited to the combination of claims at the time of the application. Furthermore, the technologies exemplified in this specification or drawings are capable of achieving a plurality of purposes simultaneously and by achieving one thereof by itself it has technological usefulness.

### EXPLANATION OF THE REFERENCE NUMERALS

2: Vertical semiconductor device operating as a MOS
4: Element region
6: Peripheral region
8: Outer circumference of a semiconductor substrate
9: Semiconductor substrate
10: Front surface electrode (source electrode)
12: Second conductivity type region (p-type body region)
14: Rear surface side first conductivity type region (n-type drift region)
16: First conductivity type region (n-type drain region)
18: Rear surface electrode (drain electrode)
20: Front surface side first conductivity type region (n-type source region)
22: Body contact layer
24: Gate insulation film
26: Trench gate electrode
30: Second conductivity type high impurity concentration ring-like region (guard ring)
32: Second conductivity type low impurity concentration layer (resurf layer)
36: First conductivity type region
40: Second conductivity type floating layer (p-type floating layer)

1. A vertical semiconductor device comprising
an element region and a peripheral region circulating the element region when a semiconductor substrate is in a planar view,
wherein the element region comprises;
a front surface electrode formed on the semiconductor substrate, a rear surface electrode formed on the rear surface of the semiconductor substrate, a front surface side first conductivity type region conductive to the front surface electrode, a rear surface side first conductivity type region conductive to the rear surface electrode, a second conductivity type region separating the front surface side first conductivity type region and the rear surface side first conductivity type region, and a gate electrode facing the second conductivity type region through a gate insulation film at a position separating the front surface side first conductivity type region and the rear surface side first conductivity type region, and
a voltage of the gate electrode changes a resistance between the front surface electrode and the rear surface electrode; and
the peripheral region comprises;
a multiple structure of a second conductivity type low impurity concentration layer formed in a range facing the front surface of the semiconductor substrate and a second conductivity type high impurity concentration ring-like region circulating the element region in a range facing the front surface of the semiconductor substrate; and
the second conductivity type high impurity concentration ring-like region extends deeply to the rear surface side from the second conductivity type low impurity concentration layer.

2. The vertical semiconductor device described in claim 1, wherein the semiconductor substrate is formed of SiC, and
a second conductivity type high impurity concentration region which forms an ohmic contact with the front surface electrode is formed on a partial surface of the second conductivity type low impurity concentration layer, and
the depth of the second conductivity type high impurity concentration region is less than the depth of the second conductivity type low impurity concentration layer, which is less than the depth of the second conductivity type high impurity concentration ring-like region.

3. The vertical semiconductor device described in claim 1, wherein the semiconductor substrate is formed of SiC, and
a second conductivity type high impurity concentration region which forms an ohmic contact with the front surface electrode is formed on a partial surface of the second conductivity type low impurity concentration layer, and
the impurity concentration ratio of the second conductivity type high impurity concentration region is larger than the impurity concentration ratio of the second conductivity type high impurity concentration ring-like region, which is larger than the impurity concentration ratio of the second conductivity type low impurity concentration layer.

4. The vertical semiconductor device described in claim 1, wherein the semiconductor substrate is formed of SiC, and
a second conductivity type floating layer is formed at an intermediate depth of the rear surface side first conductivity type region.
